(19) United States
(12) Patent Application Publication
(10) Pub. No.: US 2024/0162399 A1
(43) Pub. Date: May 16, 2024

(54) DRIVE BACKPLANE AND METHOD FOR PREPARING SAME, LIGHT-EMITTING SUBSTRATE AND METHOD FOR PREPARING SAME

(71) Applicant: GUANGZHOU CHINA STAR OPTOELECTRONICS SEMICONDUCTOR DISPLAY TECHNOLOGY CO., LTD., Guangzhou, Guangdong (CN)

(72) Inventor: Paijie Chen, Guangzhou, Guangdong (CN)

(73) Assignee: GUANGZHOU CHINA STAR OPTOELECTRONICS SEMICONDUCTOR DISPLAY TECHNOLOGY CO., LTD., Guangzhou, Guangdong (CN)

(21) Appl. No.: 17/756,660

(22) PCT Filed: May 13, 2022
(86) PCT No.: PCT/CN2022/092621

§ 371 Date: Nov. 2, 2023

(30) Foreign Application Priority Data
Apr. 27, 2022 (CN) 202210454359.0

(51) Int. Cl. H01L 33/62; H01L 25/075; H01L 33/10

(52) U.S. Cl. CPC H01L 33/62; H01L 25/0753; H01L 33/10; H01L 2933/0066

(57) ABSTRACT

A drive backplane and a method for preparing same, a light-emitting substrate and a method for preparing same. The drive backplane includes a driving substrate, a reflective layer, and a number of barriers, wherein the driving substrate includes a base substrate and connecting components disposed on the base substrate, and the connecting components are used to connect to light-emitting devices. The drive backplane can avoid a phenomenon that the reflective layer covers the connecting components, and the reflective layer covers a larger area on the drive backplane and reflectivity is relatively high.

### FIELD OF DISCLOSURE

The present application relates to a field of display technology, and in particular, to a drive backplane and a method for preparing same, a light-emitting substrate and a method for preparing same.

### BACKGROUND

Mini light-emitting diode (mini LED), also known as sub-millimeter light-emitting diode, is a new type of display technology that enables a size of light-emitting diode (LED) to be between 100 m and 200 μm. Among mini LEDs, each LED may be individually addressed and driven to emit light, so it has advantages of high efficiency, high brightness, high reliability, fast response time, and large screen, etc. Meanwhile, mini LED display products also have the advantages of thinness and low power consumption, thus are increasingly favored by consumers.

### SUMMARY

### Technical Problem

Positive electrodes and negative electrodes of mini LEDs are typically coupled to pads on a drive backplane, so as to realize lighting of the mini LEDs via the drive backplane. In a preparing process of the drive backplane, white oil for reflecting light given off by the mini LEDs is coated on peripheral regions of the pads on the drive backplane, so as to improve light utilization and light-emitting uniformity of the mini LEDs. But due to good fluidity of the white oil, it is easy to cover the pads during a flow process, which affects conduction and soldering reliability of the mini LEDs. In order to solve the above-mentioned problem, an opening area of the white oil is usually increased, that is, when printing the white oil, printing site of the white oil is away from the pads, but in such a case, it results in lower coverage area of the white oil on the drive backplane and lower reflectivity, which further causes lower light utilization and poorer light-emitting uniformity of the mini LEDs.

### Technical Solution

The embodiments of the present application provide a drive backplane and a method for preparing same, a light-emitting substrate and a method for preparing same, which may avoid a phenomenon that a reflective layer covers connecting components, and the reflective layer covers a large area on the drive backplane and the reflectivity is relatively high. In a case that light-emitting devices are disposed on the connecting components of the drive backplane to form a light-emitting substrate, a light utilization of the light-emitting device as well as a light-emitting uniformity of the light-emitting substrate will be improved.

In a first aspect, an embodiment of the present application provides a drive backplane, including:
a driving substrate, including a base substrate and connecting components disposed on the base substrate, and the connecting components are used to connect to light-emitting devices;
a reflective layer, disposed on one side of the base substrate where the connecting components are disposed, and the reflective layer is disposed on a periphery of the connecting components;
a number of barriers, disposed on the one side of the base substrate where the connecting components are disposed, and the barriers are disposed around the connecting components and the barriers are embedded in the reflective layer.

In some embodiments, a number of openings are defined on the reflective layer, groups of the connecting components are disposed on the base substrate, and each opening is provided with a group of the connecting components; a sum of areas of the number of openings is a, an area of the reflective layer is b, and an aperture ratio a/(a+b) is 0.2%-30%.

In some embodiments, a cross-section of the barriers is circular, and a diameter of the cross-section of the barriers is 1 μm-150 μm, and a height of the barriers is 30 μm-150 μm.

In some embodiments, a height of the barriers is greater than or equal to a thickness of the reflective layer;
a top surface of a region between adjacent barriers on the reflective layer shows an arc surface recessed facing the base substrate.

In some embodiments, the connecting components include a number of connecting pieces, and a distance between a connecting piece and an adjacent barrier is 50 μm-200 μm;
a distance between adjacent barriers is 30 μm-200 μm.

In some embodiments, a material of the barriers includes a photoresist material.

In some embodiments, at least one ring of the barriers is disposed on a periphery of each group of the connecting components, and the barriers of a same ring are located on sides of a central symmetric figure.

In a second aspect, an embodiment of the present application provides a method for preparing a drive backplane, including:
providing a driving substrate, the driving substrate includes a base substrate and connecting components disposed on the base substrate, and the connecting components are used to connect to light-emitting devices;
disposing a number of barriers corresponding to a periphery of the connecting components on the base substrate, so that a number of barriers are disposed around the connecting components;
disposing an ink material corresponding to the periphery of the connecting components on the base substrate, the ink material is connected with the number of barriers, and a reflective layer is formed after the ink material is cured, so that the barriers are embedded in the reflective layer.

In some embodiments, the step of disposing the number of barriers corresponding to the periphery of the connecting components on the base substrate includes:
disposing a photoresist material on the base substrate to form a photoresist layer;
patterning the photoresist layer by means of exposure and development to form the number of barriers located on the periphery of the connecting components.

In some embodiments, the ink material corresponding to the periphery of the connecting components is disposed on the base substrate by screen printing or inkjet printing.

In a third aspect, an embodiment of the present application provides a light-emitting substrate, including:
a drive backplane, the drive backplane is the above-mentioned drive backplane, or is a drive backplane obtained by the above-mentioned method for preparing the drive backplane;
light-emitting devices, the light-emitting devices are electrically connected to the connecting components of the drive backplane.

In a fourth aspect, an embodiment of the present application provides a method for preparing a light-emitting substrate, including:
providing the above-mentioned drive backplane, or preparing the drive backplane according to the above-mentioned method for preparing the drive backplane;
providing light-emitting devices, so that the light-emitting devices are electrically connected to the connecting components of the drive backplane to obtain the light-emitting substrate.

ADVANTAGES OF THE PRESENT APPLICATION

There is provided with a drive backplane in the embodiments of the present application. By disposing a number of barriers in the reflective layer, the reflective layer can be implemented as follows: first, the number of barriers are disposed on the base substrate, and then the ink material is disposed on the base substrate to form the reflective layer, and under the blocking effect of the barriers, the fluidity of the ink material decreases, and due to a surface tension between an outer surface of the barriers and the ink material, the ink material is attracted by the outer surface of the barriers, thereby reducing the fluidity of the ink material. In addition, when the fluidity of the ink material decreases, the ink material does not easily flow to a position of the connecting components, thereby avoiding a problem of the connecting components being covered by the ink material, which can improve soldering yield. In addition, when the fluidity of the ink material decreases, the ink material can be disposed at a position close to the connecting components when the ink material is applied, so as to reduce an area of the opening surrounded by the inner edge of the reflective layer and to increase a coverage area of the ink material (namely, the reflective layer) on the drive backplane, and when the light-emitting devices are disposed on the connecting components of the drive backplane to form a light-emitting substrate, the drive backplane has a high reflectivity for the lights given off by the light-emitting devices, which not only can improve the light utilization of the light-emitting devices, but also avoid a formation of dark regions between adjacent light-emitting devices, thereby improving the light-emitting uniformity of the light-emitting substrate.

### BRIEF DESCRIPTION OF THE DRAWINGS

To describe technical solutions in implementations of the present application more clearly, the following briefly introduces the accompanying drawings required for describing the implementations. Apparently, the accompanying drawings in the following description illustrate some implementations of the present application. Those of ordinary skill in the art may also obtain other drawings based on these accompanying drawings without creative efforts.

For a more complete understanding of the present application and advantages thereof, the following description will be made in conjunction with the accompanying drawings, where same reference numerals in the following indicate same parts.

FIG. 1 is a first schematic top view of a drive backplane provided by an embodiment of the present application.

FIG. 2 is an enlarged schematic view of a region C in the drive backplane of FIG. 1.

FIG. 3 is a schematic cross-sectional view of the drive backplane of FIG. 2 along an A-A direction.

FIG. 4 is a second schematic top view of a partial area of the drive backplane provided by an embodiment of the present application.

FIG. 5 is a schematic cross-sectional view of the drive backplane of FIG. 4 along a B-B direction.

FIG. 6 is a flowchart of a method for preparing a drive backplane provided by an embodiment of the present application.

FIG. 7 is a schematic structural diagram of a driving substrate provided by an embodiment of the present application.

FIG. 8 is a schematic diagram of forming a photoresist layer on a base substrate provided by an embodiment of the present application.

FIG. 9 is a schematic diagram of the photoresist layer after patterning provided by an embodiment of the present application.

FIG. 10 is a schematic cross-sectional view of a light-emitting substrate provided by an embodiment of the present application.

FIG. 11 is a flowchart of a method for preparing a light-emitting substrate provided by an embodiment of the present application.

### DETAILED DESCRIPTION

Technical solutions in the implementations of the present application will be described clearly and completely hereinafter with reference to the accompanying drawings in the implementations of the present application. Apparently, the described implementations are merely some rather than all implementations of the present application. All other implementations obtained by those of ordinary skill in the art based on the implementations of the present application without creative efforts shall fall within the protection scope of the present application.

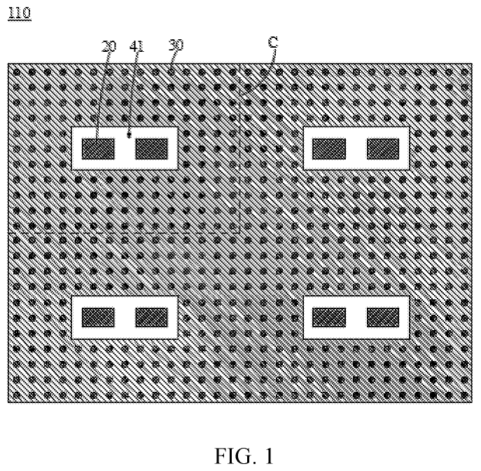

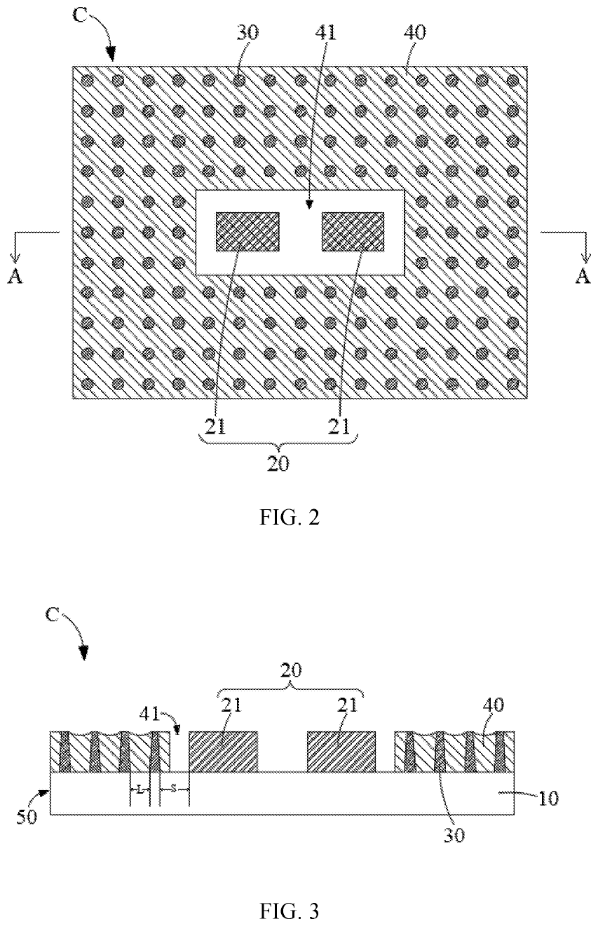

Please refer to FIGS. 1 to 3. FIG. 1 is a first schematic top view of a drive backplane provided by an embodiment of the present application, FIG. 2 is an enlarged schematic view of a region C in the drive backplane of FIG. 1, and FIG. 3 is a schematic cross-sectional view of the drive backplane of FIG. 2 along an A-A direction. An embodiment of the present application provides a drive backplane 110, including a driving substrate 50, a reflective layer 40, and a number of barriers 30. In the embodiments of the present application, “a number of” refers to one or more, and “a plurality of” refers to two or more, such as three, four, five, six, seven, eight, and so on.

Wherein the driving substrate 50 includes a base substrate 10 and connecting components 20 disposed on the base substrate 10, and the connecting components 20 are used to connect to light-emitting devices 120.

The reflective layer 40 is disposed on one side of the base substrate 10 where the connecting components 20 are disposed, and the reflective layer 40 is disposed on a periphery of the connecting components 20.

The number of barriers 30 are disposed on the one side of the base substrate 10 where the connecting members 20 are disposed, and the number of barriers 30 are disposed around the connecting members 20, and the number of barriers 30 are embedded in the reflective layer 40.

It should be noted that the drive backplane 110 is provided in the embodiments of the present application. By disposing the number of barriers 30 in the reflective layer 40, the reflective layer 40 can be implemented as follows: first, the number of barriers 30 are disposed on the base substrate 10, and then an ink material is disposed on the base substrate 10 to form the reflective layer 40, and under a blocking effect of the barriers 30, a fluidity of the ink material decreases, and due to surface tension between an outer surface of the barriers 30 and the ink material, the ink material is attracted by the outer surface of the barriers 30, thereby reducing the fluidity of the ink material. In addition, when the fluidity of the ink material decreases, the ink material does not easily flow to a position of the connecting components 20, thereby avoiding a problem of the connecting components 20 being covered by the ink material, which can improve soldering yield. In addition, when the fluidity of the ink material decreases, the ink material can be disposed at a position close to the connecting components 20 when the ink material is applied, so as to reduce an area of the opening surrounded by an inner edge of the reflective layer 40 and to increase a coverage area of the ink material (namely, the reflective layer 40) on the drive backplane 110, and when the light-emitting devices 120 are disposed on the connecting components 20 of the drive backplane 110 to form a light-emitting substrate 100, the drive backplane 110 has a high reflectivity for light given off by the light-emitting devices 120, which not only can improve light utilization of the light-emitting devices 120, but also avoid a formation of dark regions between adjacent light-emitting devices 120, thereby improving a light-emitting uniformity of the light-emitting substrate 100.

Referring to FIG. 1, a number of openings 41 are defined on the reflective layer 40, groups of the connecting components 20 are disposed on the base substrate 10. Each opening 41 is provided with a group of the connecting components 20, and a sum of areas of openings 41 is a, and an area of the reflective layer 40 is b, and an aperture ratio a/(a+b) is 0.2%-30%, such as 0.2%, 0.4%, 0.6%, 0.8%, 1%, 2%, 3%, 4%, 5%, 6%, 7%, 8%, 9%, 10%, 13%, 15%, 17%, 20%, 22%, 25%, 28%, 30%, etc. It can be seen that the reflective layer 40 has a relatively small aperture ratio. In a case that the aperture ratio of the reflective layer 40 is relatively small, the coverage area of the reflective layer 40 on the drive backplane 110 is relatively large, so that reflectivity of the reflective layer 40 to the light-emitting devices 120 can be increased.

Exemplarily, a cross-section of the barriers 30 is circular, and a diameter of the cross-section of the barriers 30 is 1 μm-150 μm, such as 1 μm, 3 μm, 5 μm, 7 μm, 10 μm, 12 μm, 15 μm, 18 μm, 20 μm, 23 μm, 25 μm, 27 μm, 30 μm, 50 μm, 70 μm, 100 μm, 130 μm, 150 μm, etc. It should be noted that the cross-section of the barriers 30 refers to a cross-section obtained by cutting the barriers 30 in a direction parallel to the base substrate 10 in the embodiment of the present application. It should be understood that the cross-section of the barriers 30 can also be in other shapes, such as triangular, rectangular (rectangular or square), regular pentagonal, regular hexagonal, star, and irregular shape and the like.

Referring to FIG. 1, the barriers 30 may be in the shape of a truncated cone, that is, a cross-sectional area of the barriers 30 gradually increases from one side away from the base substrate 10 to one side close to the base substrate 10. Certainly, a shape of the barriers 30 can also be set such that the cross-sectional area of the barriers 30 gradually decreases or remains uniform, from one side away from the base substrate 10 to one side close to the base substrate 10.

Exemplarily, a height of the barriers 30 may be 30 μm-150 μm, such as 30 μm, 40 am, 50 μm, 70 μm, 80 μm, 90 μm, 100 μm, 110 μm, 120 μm, 130 μm, 140 μm, 150 μm, and the like. It should be understood that the height of the barriers 30 refers to a distance between a side surface of the barriers 30 away from the base substrate 10 and a side surface of the barriers 30 connected to the base substrate 10.

Exemplarily, a thickness of the reflective layer 40 may be 30 μm-150 μm, such as 30 μm, 40 μm, 50 μm, 70 μm, 80 μm, 90 μm, 100 μm, 110 μm, 120 μm, 130 μm, 140 μm, 150 μm, and the like. It should be understood that the thickness of the reflective layer 40 refers to a distance between a side surface of the reflective layer 40 away from the base substrate 10 and a side surface of the reflective layer 40 connected to the base substrate 10.

Please refer to FIG. 1, the height of the barriers 30 may be greater than or equal to the thickness of the reflective layer 40.

It should be noted that when the height of the barriers 30 is greater than or equal to the thickness of the reflective layer 40, due to an effect of surface tension, a top surface of a region between adjacent barriers 30 on the reflective layer 40 (that is, the side surface of the reflective layer 40 away from the base substrate 10) shows an arc surface recessed facing the base substrate 10, so that an upper surface of the reflective layer 40 shows uneven shapes to realize an effect of diffuse reflection, and reflected light from different regions on the reflective layer 40 shows a relatively uniform output intensity. In a case that the light-emitting devices 120 are arranged on the connecting components 20 of the drive backplane 110 to form the light-emitting substrate 100, the light-emitting uniformity of different regions on the light-emitting substrate 100 is better. It should be noted that when the top surface of the reflective layer 40 is of uneven shapes, the thickness of the reflective layer 40 is an average value of thicknesses of all regions.

Certainly, in other embodiments, the height of the barriers 30 may also be less than the thickness of the reflective layer 40. In this case, the reflective layer 40 covers a top surface of the barriers 30 (that is, the side surface of the barrier 30 away from the base substrate 10), the top surface of the reflective layer 40 is flat, and the diffuse reflection effect of the top surface of the reflective layer 40 is poor at this time, the reflectivity is however high.

Exemplarily, each group of the connecting components 20 may include a number of connecting pieces 21 spaced apart, and distance S between each connecting piece 21 and an adjacent barrier 30 is 50 μm-200 μm, that is, among the number of barriers 30 disposed around the connecting components 20, the distance S between the barrier 30 disposed closest to the connecting piece 21 and the connecting piece 21 is set to 50 μm-200 μm, so that when the ink material is arranged to form the reflective layer 40, a buffer distance is provided for the flow of the ink material, so as to prevent the ink material from flowing onto the connecting piece 21 and causing the connecting piece 21 to be covered. Exemplarily, the distance S between each connecting piece 21 and the adjacent barrier 30 may be 50 μm, 70 μm, 100 μm, 120 μm, 150 μm, 180 μm, 200 μm, and the like.

Exemplarily, the connecting members 21 may be a pad, namely, the connecting members 21 are connected to the light-emitting devices 120 by soldering. Exemplarily, a material of the connecting members 21 may be metal, such as one or more of molybdenum (Mo), titanium (Ti), and copper (Cu).

Please combine FIG. 1, each connecting component 20 may include two connecting pieces 21 spaced apart, one for connecting to a positive pole of the light-emitting devices 120, and another for connecting to a negative pole of the light-emitting devices 120.

Exemplarily, a distance L between adjacent barriers 30 may be 30 μm-200 μm, such as 30 μm, 50 μm, 80 μm, 100 μm, 130 μm, 150 μm, 170 μm, 200 μm, and the like. By setting the distance between adjacent barriers 30 to within a suitable range (30 μm-200 μm), the number of barriers 30 can effectively block the ink material when the ink material is disposed to form the reflective layer 40, thereby reducing the fluidity of the ink material.

Exemplarily, a material of the barriers 30 may be a photoresist material, such as a positive photoresist material or a negative photoresist material. In a case that the material of the barriers 30 is a photoresist material, the barriers 30 may be prepared by coating a photoresist, and by exposure and development.

Exemplarily, a color of the reflective layer 40 may be white, so as to have a better reflective effect. A material of the reflective layer 40 may be an insulating material (e.g., resin material, etc.), so as to protect lines on the driving substrate 50 when the connecting pieces 21 and the light-emitting devices 120 are soldered.

Exemplarily, the base substrate 10 may be a thin film transistor (TFT) substrate, namely, the base substrate 10 includes TFT devices, so that the light-emitting devices 120 can be controlled to turn on or off by using the TFT devices.

Referring to FIGS. 1-5, at least one ring of barriers 30 is disposed on a periphery of each group of the connecting components 20, and the barriers 30 of a same ring are located on sides of a central symmetric figure. Exemplarily, the central symmetric figure may be a rectangle, a square, a circle, a triangle, a rhombus, and the like. When each group of the connecting components 20 includes two connecting pieces 21, a center symmetry point of the central symmetric figure may coincide with a midpoint of a line connecting geometric centers of the two connecting pieces 21.

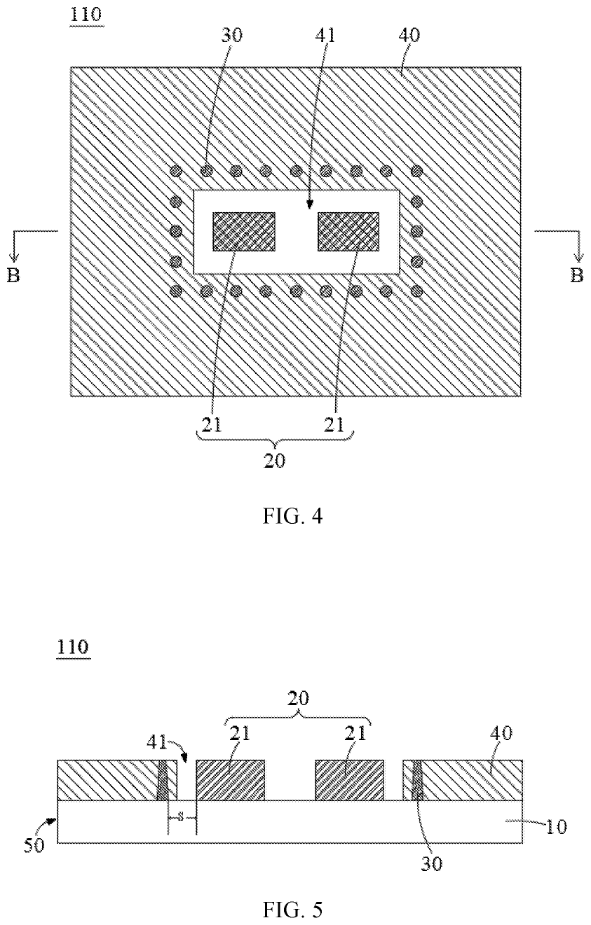

Please refer to FIGS. 4-5, FIG. 4 is a second schematic top view of a partial area of the drive backplane provided by an embodiment of the present application, and FIG. 5 is a schematic cross-sectional view of the drive backplane of FIG. 4 along a B-B direction. By comparing the embodiments shown in FIGS. 1-3 with the embodiments shown in FIGS. 4-5, it can be seen that in the embodiments shown in FIGS. 1-3, a number of rings of barriers 30 are disposed on the periphery of each group of the connecting components 20, and the barriers 30 of the same ring are located on sides of a rectangle, so that all regions of the reflective layer 40 are provided with the barriers 30. In the embodiments shown in FIGS. 4-5, a ring of barriers 30 are provided on the periphery of each group of the connecting components 20, and the barriers 30 of the same ring are located on sides of the rectangle, that is, the barriers 30 are merely provided in the regions of the reflective layer 40 close to the connecting components 20. As shown in FIGS. 1-3, the number of barriers 30 are arranged in multiple rings on the periphery of the connecting components 20, and the multiple rings may be two or more rings, such as three rings, four rings, five rings, six rings, and the like. As shown in FIGS. 4-5, the number of barriers 30 are arranged in a ring on the periphery of the connecting component 20.

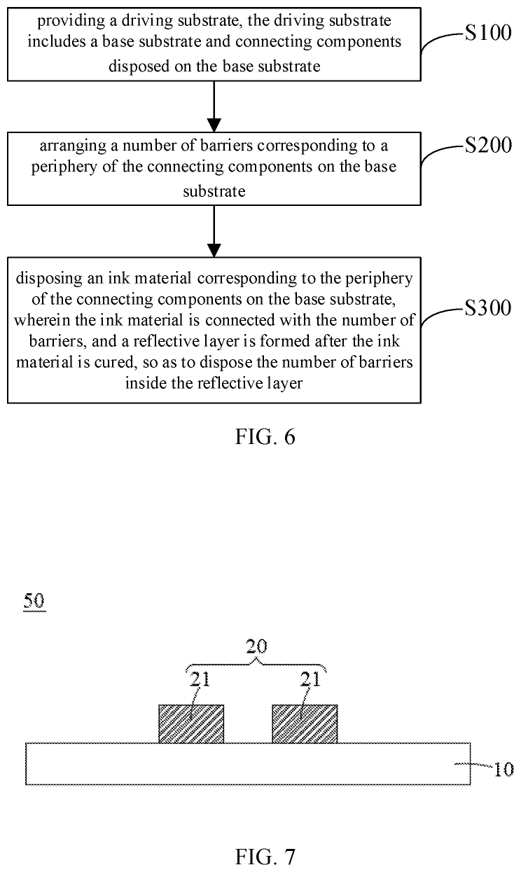

Please refer to FIG. 6. FIG. 6 is a flowchart of a method for preparing a drive backplane provided by an embodiment of the present application. An embodiment of the present application provides a method for preparing a drive backplane, including:

S100, with reference to FIG. 7, providing a driving substrate 50, the driving substrate 50 includes a base substrate 10 and connecting components 20 disposed on the base substrate 10.

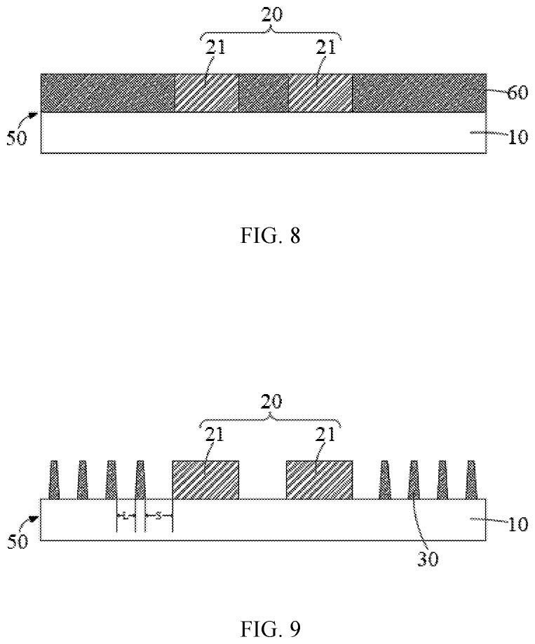

S200, with reference to FIGS. 8-9, arranging a number of barriers 30 corresponding to a periphery of the connecting components 20 on the base substrate 10, so as to arrange the number of barriers 30 around the connecting components 20.

With reference to FIGS. 8-9, the step of “arranging a number of barriers 30 corresponding to the periphery of the connecting components 20 on the base substrate 10” may include:
with reference to FIG. 8, disposing a photoresist material on the base substrate 10 to form a photoresist layer 60;
with reference to FIG. 9, patterning the photoresist layer 60 by means of exposure and development to form a number of barriers 30 located on the periphery of the connecting components 20.

S300, with reference to FIG. 9 and FIG. 3, disposing an ink material corresponding to the periphery of the connecting components 20 on the base substrate 10, the ink material is connected with the number of barriers 30, and a reflective layer 40 is formed after the ink material is cured, so as to dispose the number of barriers 30 inside the reflective layer 40.

It should be understood that when the ink material corresponding to the periphery of the connecting components 20 is provided on the base substrate 10, the ink material may be applied between adjacent barriers 30, or may be applied on the periphery (namely, a side away from the connecting components 20) of the number of barriers 30.

Exemplarily, the ink material corresponding to the periphery of the connecting components 20 may be disposed on the base substrate 10 by means of screen printing or inkjet printing.

In the preparing method of the drive backplane provided by the embodiment of the present application, the number of barriers 30 are firstly arranged on the base substrate 10, and then the ink material for forming the reflective layer 40 is arranged on the base substrate 10. Under the blocking effect of the barriers 30, the fluidity of the ink material decreases, and due to the surface tension between the outer surface of the barriers 30 and the ink material, the ink material can be attracted by the outer surface of the barriers 30, thereby reducing the fluidity of the ink material. When the fluidity of the ink material decreases, the ink material does not easily flow to the position of the connecting components 20, thereby avoiding the problem of the connecting components 20 being covered by the ink material, which can improve the soldering yield. In addition, when the fluidity of the ink material decreases, the ink material can be disposed at a position close to the connecting components 20 when the ink material is applied, so as to reduce the area of the opening 41 surrounded by the inner edge of the reflective layer 40, and to increase the coverage area of the ink material (namely, the reflective layer 40) on the drive backplane 110. When the light-emitting devices 120 are disposed on the connecting components 20 of the drive backplane 110 to form the light-emitting substrate 100, the drive backplane 110 has a high reflectivity for the lights given off by the light-emitting devices 120, which not only can improve the light utilization of the light-emitting devices 120, but also avoid the formation of dark regions between adjacent light-emitting devices 120, thereby improving the light-emitting uniformity of the light-emitting substrate 100.

In the related art, in order to reduce the fluidity of the ink material, a small amount of ink material is usually printed each time, and total amount of ink material required for preparing the reflective layer 40 is achieved by multiple printings, but this method reduces printing speed and increases printing cost due to large number of printing times and long printing time. In the preparing method of the drive backplane of the embodiment of the present application, the fluidity of the ink material is reduced by using the barriers 30, so that the ink material for preparing the reflective layer 40 can be printed in one printing process, thereby improving printing efficiency and reducing printing costs.

Exemplarily, a number of openings 41 are defined on the reflective layer 40, groups of the connecting components 20 are disposed on the base substrate 10, and each opening 41 is provided with a group of the connecting components 20. The sum of the areas of the number of openings 41 is a, and the area of the reflective layer 40 is b, and the aperture ratio a/(a+b) is 0.2%-30%.

Exemplarily, the cross-section of the barriers 30 is circular, the diameter of the cross-section of the barriers 30 is 1 μm-150 μm, and the height of the barriers 30 is 30 μm-150 μm.

Exemplarily, the thickness of the reflective layer 40 is 30 μm-150 μm.

Exemplarily, the top surface of the region between adjacent barriers 30 on the reflective layer 40 shows an arc surface recessed facing the base substrate 10.

Exemplarily, each group of the connecting components 20 includes the number of connecting pieces 21 spaced apart, and the distance S between each connecting piece 21 and the adjacent barrier is 50 μm-200 μm.

Exemplarily, the distance L between adjacent barriers 30 is 30 μm-200 μm.

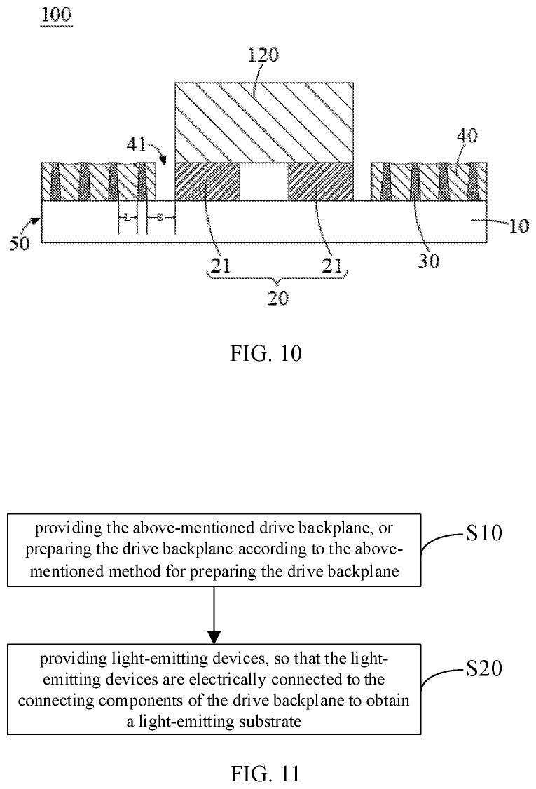

Please refer to FIG. 10. FIG. 10 is a schematic cross-sectional view of a light-emitting substrate provided by an embodiment of the present application. The embodiment of the present application provides a light-emitting substrate 100, including a drive backplane 110 and light-emitting devices 120, wherein the drive backplane 110 may be the drive backplane 110 in any of the above-mentioned embodiments, or the drive backplane 110 obtained by the method for preparing the drive backplane in any of the above-mentioned embodiments; the light-emitting devices 120 are electrically connected to the connecting components 20 of the drive backplane 110.

Referring to FIG. 10, when each group of the connecting components 20 includes two connecting pieces 21 spaced apart, a positive pole of the light-emitting devices 120 is connected to one of the connecting pieces 21, and a negative pole of the light-emitting devices 120 is connected to another connecting piece 21.

Exemplarily, the light-emitting devices 120 are LED devices, such as mini LEDs, micro LEDs, and the like.

It should be noted that the light-emitting substrate 100 may be a display panel, that is, used for displaying images, or the light-emitting substrate 100 may be used as a light source in a liquid crystal display device to provide backlight for a liquid crystal display panel.

Exemplarily, the light-emitting substrate 100 may be applied to display devices such as televisions, tablet computers, notebook computers, mobile phones, computer monitors, and advertising screens.

Please refer to FIG. 11, in conjunction with FIG. 3 and FIG. 10. FIG. 11 is a flowchart of a method for preparing a light-emitting substrate provided by an embodiment of the present application. The embodiment of the present application provides a method for preparing the light-emitting substrate, including:

S10, with reference to FIG. 3, providing the drive backplane 110 in any of the above-mentioned embodiments, or preparing the drive backplane 110 according to the method for preparing the drive backplane in any of the above-described embodiments.

S20, with reference to FIG. 10, providing the light-emitting devices 120, so that the light-emitting devices 120 are electrically connected to the connecting components 20 of the drive backplane 110 to obtain the light-emitting substrate 100.

Exemplarily, the light-emitting devices 120 are electrically connected to the connecting components 20 in the drive backplane 110 by soldering.

The drive backplane and the preparing method thereof, the light-emitting substrate and the preparing method thereof provided in the embodiments of the present application have been described in detail above. The specific examples herein are utilized to illustrate the principles and embodiments of the application. The description of the embodiments above is designed to assist in understanding the method and ideas of the present application. At the same time, persons skilled in the art could, based on the ideas in the application, make alterations to the specific embodiments and application scope, and thus the content of the present specification should not be construed as placing limitations on the present application.

What is claimed is:

1. A drive backplane, comprising:
a driving substrate, the driving substrate comprising a base substrate and connecting components disposed on the base substrate, and the connecting components are used to connect to light-emitting devices;
a reflective layer, disposed on one side of the base substrate where the connecting components are disposed, and the reflective layer is disposed on a periphery of the connecting components;
a number of barriers, disposed on the one side of the base substrate where the connecting components are disposed, and the barriers are disposed around the connecting components, and the barriers are embedded in the reflective layer.

2. The drive backplane as claimed in claim 1, wherein a number of openings are defined on the reflective layer, groups of the connecting components are disposed on the base substrate, and each opening is provided with a group of the connecting components; a sum of areas of the number of openings is a, an area of the reflective layer is b, and an aperture ratio a/(a+b) is 0.2%-30%.

3. The drive backplane as claimed in claim 1, wherein a cross-section of the barriers is circular, a diameter of the cross-section of the barriers is 1 μm-150 μm, and a height of the barriers is 30 μm-150 μm.

4. The drive backplane as claimed in claim 1, wherein a height of the barriers is greater than or equal to a thickness of the reflective layer;
a top surface of a region between adjacent barriers on the reflective layer shows an arc surface recessed facing the base substrate.

5. The drive backplane as claimed in claim 1, wherein the connecting components comprise a number of connecting pieces, and a distance between a connecting piece and an adjacent barrier is 50 μm-200 μm;
a distance between adjacent barriers is 30 μm-200 μm.

6. The drive backplane as claimed in claim 1, wherein a material of the barriers comprises a photoresist material.

7. The drive backplane as claimed in claim 1, wherein at least one ring of the barriers is disposed on a periphery of each group of the connecting components, and the barriers of a same ring are located on sides of a central symmetric figure.

8. A method for preparing a drive backplane, comprising:
providing a driving substrate, the driving substrate comprises a base substrate and connecting components disposed on the base substrate, and the connecting components are used to connect to light-emitting devices;
disposing a number of barriers corresponding to a periphery of the connecting components on the base substrate, so that a number of barriers are disposed around the connecting components;
disposing an ink material corresponding to the periphery of the connecting components on the base substrate, the ink material is connected with the number of barriers, and a reflective layer is formed after the ink material is cured, so that the barriers are embedded in the reflective layer.

9. The method for preparing the drive backplane as claimed in claim 8, wherein the step of disposing the number of barriers corresponding to the periphery of the connecting components on the base substrate comprises:
disposing a photoresist material on the base substrate to form a photoresist layer;
patterning the photoresist layer by means of exposure and development to form the number of barriers located on the periphery of the connecting components.

10. The method for preparing the drive backplane as claimed in claim 8, wherein the ink material corresponding to the periphery of the connecting components is disposed on the base substrate by screen printing or inkjet printing.

11. The method for preparing the drive backplane as claimed in claim 8, wherein a number of openings are defined on the reflective layer, groups of the connecting components are disposed on the base substrate, and each opening is provided with a group of the connecting components; a sum of areas of the number of openings is a, an area of the reflective layer is b, and an aperture ratio a/(a+b) is 0.2%-30%.

12. The method for preparing the drive backplane as claimed in claim 8, wherein a cross-section of the barriers is circular, a diameter of the cross-section of the barriers is 1 μm-150 μm, and a height of the barriers is 30 μm-150 μm.

13. The method for preparing the drive backplane as claimed in claim 8, wherein a height of the barriers is greater than or equal to a thickness of the reflective layer;
a top surface of a region between adjacent barriers on the reflective layer shows an arc surface recessed facing the base substrate.

14. The method for preparing the drive backplane as claimed in claim 8, wherein the connecting components comprise a number of connecting pieces, and a distance between a connecting piece and an adjacent barrier is 50 μm-200 μm;
a distance between adjacent barriers is 30 μm-200 μm.

15. A light-emitting substrate, comprising:
a drive backplane, the drive backplane is the drive backplane as claimed in claim 1;
light-emitting devices, the light-emitting devices are electrically connected to the connecting components of the drive backplane.

16. The light-emitting substrate as claimed in claim 15, wherein a number of openings are defined on the reflective layer, groups of the connecting components are disposed on the base substrate, each opening is provided with a group of the connecting components; a sum of areas of the number of openings is a, an area of the reflective layer is b, and an aperture ratio a/(a+b) is 0.2%-30%.

17. The light-emitting substrate as claimed in claim 15, wherein a cross-section of the barriers is circular, and a diameter of the cross-section of the barriers is 1 μm-150 μm, and a height of the barriers is 30 μm-150 μm.

18. The light-emitting substrate as claimed in claim 15, wherein a height of the barriers is greater than or equal to a thickness of the reflective layer;
a top surface of a region between adjacent barriers on the reflective layer shows an arc surface recessed facing the base substrate.

19. The light-emitting substrate as claimed in claim 15, wherein the connecting components comprise a number of connecting pieces, and a distance between a connecting piece and an adjacent barrier is 50 μm-200 μm;
a distance between adjacent barriers is 30 μm-200 μm.

20. A method for preparing a light-emitting substrate, comprising:
providing the drive backplane as claimed in claim 1;
providing light-emitting devices, so that the light-emitting devices are electrically connected to the connecting components of the drive backplane to obtain the light-emitting substrate.
